(19) United States
(12) Patent Application Publication
(10) Pub. No.: US 2025/0015241 A1
(43) Pub. Date: Jan. 9, 2025

(54) METHOD OF TRANSFERRING LIGHT EMITTING CHIP, LIGHT EMITTING STRUCTURE AND DISPLAY PANEL

(71) Applicant: HKC CORPORATION LIMITED, Shenzhen (CN)

(72) Inventors: Yang PU, Shenzhen (CN); Lidan YE, Shenzhen (CN)

(21) Appl. No.: 18/668,954

(22) Filed: May 20, 2024

(30) Foreign Application Priority Data
Jul. 4, 2023 (CN) 202310811963.9

(51) Int. Cl. H01L 33/62; H01L 25/075; H01L 33/00; H01L 33/38

(52) U.S. Cl. CPC H01L 33/62; H01L 25/0753; H01L 33/0093; H01L 33/38; H01L 2933/0016; H01L 2933/0066

(57) ABSTRACT

A method includes forming a light emitting chip on a surface of a growth substrate; forming a transfer film layer on a transient substrate; forming an electrode fixing structure on a side of the transfer film layer away from the transient substrate, and opening a through-wire hole in the transfer film layer adjacent to the electrode fixing structure; making the growth substrate opposite to the transient substrate; making the light emitting transfer structure opposite to a driving backplane; and forming a connection wire, a portion of the connection wire is connected to the binding-point electrode through the through-wire hole, and another portion of the connection wire is connected to the electrode fixing structure.

### CROSS-REFERENCE TO RELATED APPLICATIONS

The present disclosure claims priority to Chinese Patent Application No. 202310811963.9, filed Jul. 4, 2023, the entire disclosure of which is incorporated herein by reference.

### TECHNICAL FIELD

The present disclosure relates to the technical field of display panels, and more specifically, to a method of transferring a light emitting chip, a light emitting structure and a display panel.

### BACKGROUND

Micro Light Emitting Diode Displays (Micro LEDs) are gradually used in display panels because of their higher stability, long life and higher resolution. In the production of the Micro LED display panels, millions to tens of millions of LED chips need to be transferred from the growth substrate to the driving backplane. During the transfer process, the growth substrate needs to be removed by means of stripping off using the laser. However, in the process of stripping off the growth substrate, the laser irradiates the driving backplane, causing wires on the driving backplane are easily broken by the laser, resulting in abnormal display of the display panel.

### SUMMARY

There are provided a method of transferring a light emitting chip, a light emitting structure, and a display panel according to the embodiments of the present disclosure. The technical solution is as below:

According to a first aspect of an embodiment of the present disclosure, the present disclosure provides a method of transferring a light emitting chip, which includes:
forming a light emitting chip on a surface of a growth substrate;
forming a transfer film layer on a transient substrate;
forming an electrode fixing structure on a side of the transfer film layer away from the transient substrate, and opening a through-wire hole in the transfer film layer adjacent to the electrode fixing structure;
making the growth substrate opposite to the transient substrate, to make an electrode of the light emitting chip on the growth substrate connect to the electrode fixing structure on the transient substrate;
stripping off the growth substrate and at least a portion of the transient substrate to form a light emitting transfer structure;
making the light emitting transfer structure opposite to a driving backplane, to make a through-wire hole in the light emitting transfer structure correspond to a binding-point electrode on the driving backplane; and
forming a connection wire, wherein a portion of the connection wire is connected to the binding-point electrode through the through-wire hole, and another portion of the connection wire is connected to the electrode fixing structure.

According to a second aspect of an embodiment of the present disclosure, the present disclosure also provides a display panel, including a light emitting chip and a driving backplane, wherein the method of transferring the light emitting chip as mentioned above is used by the display panel to transfer the light emitting chip to the driving backplane.

It should be understood in the present disclosure that the above general description and the later detailed description are only exemplary and explanatory, and do not limit the present disclosure.

### BRIEF DESCRIPTION OF THE DRAWINGS

The accompanying drawings herein are incorporated into and form a portion of the specification, illustrate embodiments in accordance with the present disclosure, and are used in conjunction with the specification to explain the principles of the present disclosure. Obviously, the accompanying drawings in the following description are only some of the embodiments of the present disclosure, and other accompanying drawings may be obtained from these drawings by those skilled in the art without creative labour.

FIG. 1 is a flowchart of a method of transferring a light emitting chip according to a first embodiment of the present disclosure.

FIG. 2 is a flowchart of providing an electrode fixing structure according to the first embodiment of the present disclosure.

FIG. 3 is a flowchart of opening a through-wire hole in a transfer film layer according to the first embodiment of the present disclosure.

FIG. 4 is a flowchart of providing an adhesive layer according to the first embodiment of the present disclosure.

FIG. 5 is a flowchart of providing an adhesive layer on an edge area of a driving backplane according to the first embodiment of the present disclosure.

FIG. 6 is a structural view of a growth substrate and a light emitting chip according to the present disclosure.

FIG. 7 is a structural view of a transient substrate and an electrode fixing structure according to the present disclosure.

FIG. 8 is a structural view of providing a glass layer and an etching blocking layer on the transient substrate according to the present disclosure.

FIG. 9 is a structural view of making the growth substrate opposite to the transient substrate according to the present disclosure.

FIG. 10 is a structural view of a light emitting transfer structure according to the present disclosure.

FIG. 11 is a structural view of a connection of a light emitting transfer structure to a driving backplane according to a second embodiment of the present disclosure.

FIG. 12 is a structural view of providing a connection wire in FIG. 11 of the present disclosure.

FIG. 13 is a structural view of providing a transient substrate between the light emitting transfer structure and the driving backplane according to the present disclosure.

FIG. 14 is a structural view of the present disclosure in which the driving backplane is provided with a dielectric layer at a position corresponding to the light emitting chip.

### DETAILED DESCRIPTION OF THE EMBODIMENTS

Embodiments will now be described more fully with reference to the accompanying drawings. However, the embodiments are capable of being implemented in a variety of forms and should not be construed as being limited to the examples set forth herein; rather, the provision of these embodiments allows the present disclosure to be more comprehensive and complete and conveys the idea of the embodiments in a comprehensive manner to those skilled in the art.

### Embodiment I

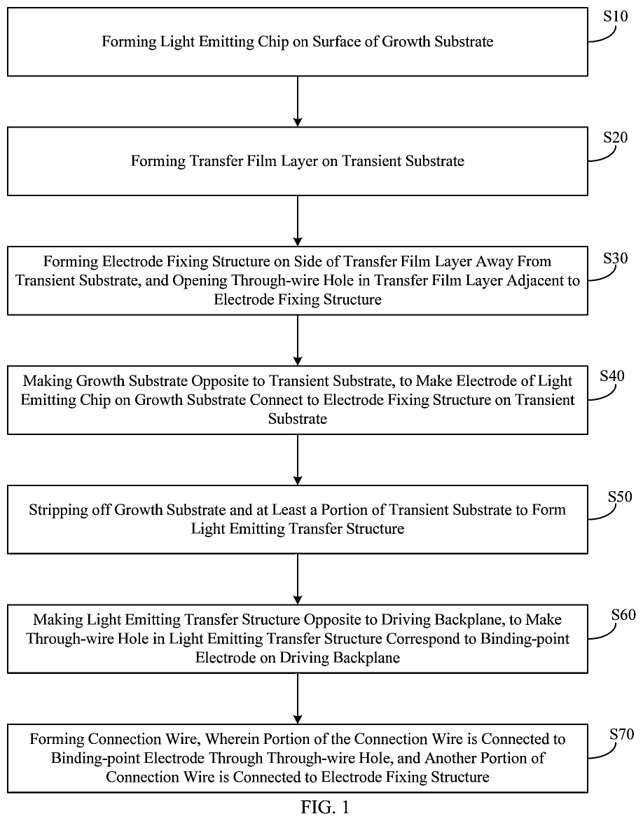

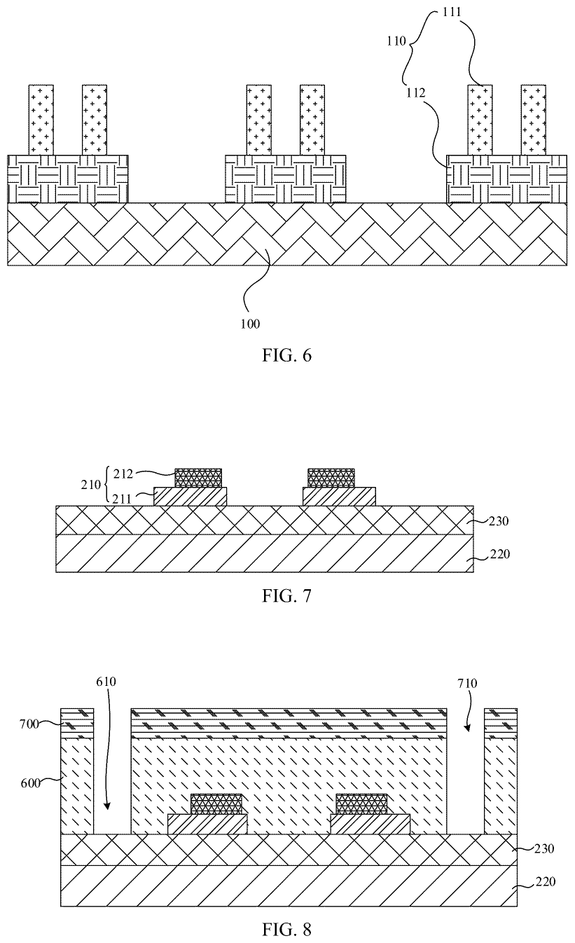

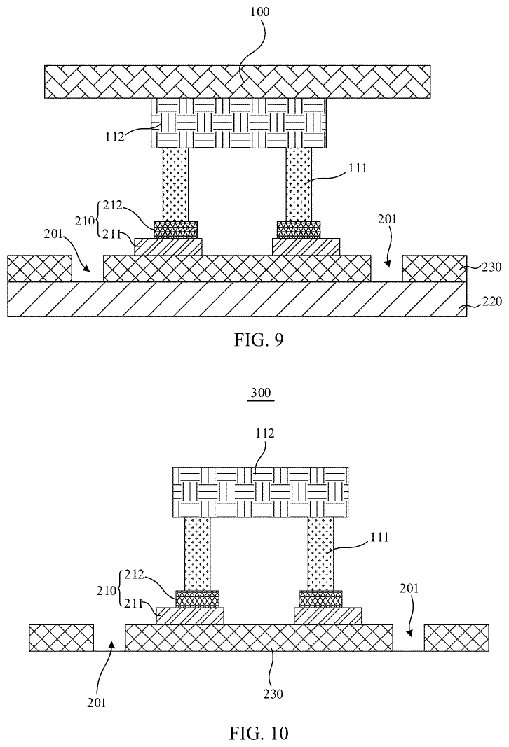

Referring to FIG. 1, FIGS. 6 to 12, the present disclosure provides a method of transferring a light emitting chip, which includes:

Step S10, forming a light emitting chip 110 on a surface of the growth substrate 100. The light emitting chip 110 is a Light Emitting Diode Display (LED). The growth substrate 100 is usually a sapphire substrate, and an epitaxial layer 112 is formed on the sapphire substrate, and electrodes 111 are fabricated and formed on a top of the epitaxial layer 112. The growth substrate 100 may also be made of glass or quartz, etc. A plurality of the light emitting chips 110 are spaced apart on the surface of the growth substrate 100.

Step S20, forming a transfer film layer 230 on the transient substrate 220. The transient substrate 220 is mainly used to support the transfer film layer 230. The material of the transient substrate 220 may be glass, quartz, or sapphire and so on. The material of the transfer film layer 230 may be a Polyimide (PI) film, or a Polyethylene Terephthalate (PET) film, which are relatively soft in texture, and the transient substrate 220 is mainly used to support the transfer film layer 230 and prevent the transfer film layer 230 from being deformed, in particular, when the through-wire hole 201 is provided, the transient substrate 220 supports and fixes the transfer film layer 230, to ensure that the position and size of the opened through-wire holes 201 are accurate.

Step S30, forming an electrode fixing structure 210 on a side of the transfer film layer 230 away from the transient substrate 220, and opening a through-wire hole 201 in the transfer film layer 230 adjacent to the electrode fixing structure 210. The transfer film layer 230 is mainly used to transfer the light emitting chip 110 to the driving backplane 400. The electrode fixing structure 210 not only can be used to fix the electrode 111 of the light emitting chip 110, but also can transmit electrical signals to the electrodes 111. The through-wire hole 201 is provided to ensure that the connection wire 500 can be connected to the driving backplane 400 and the electrode fixing structure 210, and the through-wire hole 201 is provided close to the electrode fixing structure 210, thereby reducing the length of the connection wire 500.

Step S40, making the growth substrate 100 opposite to the transient substrate 220, to make the light emitting chip 110 on the growth substrate 100 to be transferred to the transient substrate 220, and to make the electrode fixing structure 210 of the transient substrate 220 to connect the electrodes 111 of the light emitting chip 110. Making the growth substrate 100 opposite to the transient substrate 220 means that the light emitting chip 110 and the electrode fixing structure 210 are opposite to each other, and the electrode 111 of the light emitting chip 110 is directly faced to the electrode fixing structure 210. The growth substrate 100 is placed close to the transient substrate 220, or of course, both are placed close to each other. After the electrode 111 of the light emitting chip 110 contacts with the electrode fixing structure 210, the electrode fixing structure 210 can fix the electrode 111 of the light emitting chip 110, and thus the light emitting chip 110 is also fixed.

Step S50, stripping off the growth substrate 100 and at least a portion of the transient substrate 220 to form the light emitting transfer structure 300. The growth substrate 100 can be stripped off by the laser, so as to avoid the growth substrate 100 from affecting the subsequent operations. When stripping off the growth substrate 100, the light emitting chip 110 is not yet transferred to the driving backplane 400, and the binding-point electrode 410 of the driving backplane 400 will not be damaged. Moreover, the epitaxial layer 112 of the light emitting chip 110 covers the electrode fixing structure 210, thus the electrode fixing structure 210 is irradiated difficultly for the laser when the laser is used to strip off, and will not be damaged.

It is to be noted that the transient substrate 220 may be stripped off entirely or partially, i.e., a portion of the transient substrate 220 may be stripped off. As can be seen, the formed light emitting transfer structure 300 includes the light emitting chip 110 and the electrode fixing structure 210, and may also include a portion of the transient substrate 220, or may not include the transient substrate 220. In short, the through-wire hole 201 is a portion of the light emitting transfer structure 300.

Step S60, making the light emitting transfer structure 300 opposite to the driving backplane 400, to make the through-wire hole 201 on the light emitting transfer structure 300 correspond to the binding-point electrode 410 on the driving backplane 400. The electrode 111 of the light emitting chip 110 includes an anode and a cathode, and there are two through-wire holes 201. Similarly, the binding-point electrodes 410 on the driving backplane 400 can be broadly divided into two types, one for providing electrical signals to the anode of the light emitting chip 110 and the other for providing electrical signals to the cathode of the light emitting chip 110. For this purpose, two of the through-wire holes 201 correspond to different binding-point electrodes 410, and the binding-point electrodes 410 need to be exposed in the through-wire holes 201.

Step S70, forming the connection wire 500. The connection wire 500 is provided in the through-wire hole 201, so that a portion of the connection wire 500 is connected to the binding-point electrode 410 through the through-wire hole, and another portion of the connection wire 500 is connected to the electrode fixing structure 210. The connection wire 500 may be formed by means of vapour-phase deposition in conjunction with etching and so on. The connection wire 500 can be conductive, and can transmit the electrical signals from the driving backplane 400 to the light emitting chip 110. For example, the electrical signal from the driving backplane 400 passes sequentially through the binding-point electrode 410, the connection wire 500, the electrode fixing structure 210, and then to the electrode 111 of the light emitting chip 110. A potential difference is formed between the anode and the cathode of the light emitting chip 110, so as to cause the light emitting chip 110 to illuminate. The connection wire 500 may be a metal, such as gold, silver, copper, etc., or a semiconductor, such as indium tin oxide (ITO).

In this embodiment, the light emitting chip 110 is fabricated and completed on the growth substrate 100. An electrode fixing structure 210 is fabricated on the transfer film layer 230, and a through-wire hole 201 is opened close to the electrode fixing structure 210. When the growth substrate 100 and the transient substrate 220 are placed opposite each other, the electrodes 111 of the light emitting chip 110 are fixed by the electrode fixing structure 210, and then the light emitting chip 110 is also fixed at the same time. Then, the growth substrate 100 is stripped off, and at least a portion of the transient substrate 220 is stripped off, and the remaining transient substrate 220 is taken as the light emitting transfer structure 300. The light emitting transfer structure 300 is then moved to the driving backplane 400, and a connection wire 500 is made in the through-wire hole 201, and the connection wire 500 connects the binding-point electrode 410 on the driving backplane 400 to the electrode fixing structure 210. The drive signal from the binding-point electrode 410 can be transferred to the electrode fixing structure 210 through the connection wire 500, and then transferred to the light emitting chip 110 through the electrode fixing structure 210. As can be seen, when the growth substrate 100 is stripped off, the light emitting chip 110 is not yet bound to the driving backplane 400, so that there is no impact on the binding-point electrode 410 on the driving backplane 400, and the breakage of the binding-point electrode 410 can be effectively reduced. Moreover, when the connection wire 500 is provided in the through-wire hole 201, the operation of stripping off is also not involved, which further reduces the impact on the binding-point electrode 410, to reduce abnormalities in the display screen.

Referring to FIG. 2, the forming the electrode fixing structure 210 on the side of the transfer film layer 230 away from the transient substrate 220 includes:

Step S310, providing a conductive layer 211 on a surface of the transfer film layer 230. The conductive layer 211 is mainly used to transmit an electrical signal, and the conductive layer 211 may be a metal or a semiconductor. For example, the conductive layer 211 may be made of gold, silver, or copper, etc., or it may be ITO.

Step S320, providing a conductive adhesive 212 on a side of the conductive layer 211 away from the transfer film layer 230. The electrode 111 of the light emitting chip 110 is connected to the conductive layer 211 through the conductive adhesive 212. The conductive adhesive 212 is used to fix the electrode 111 of the light emitting chip 110. The conductive adhesive 212 enables the electrode 111 of the light emitting chip 110 to be inserted therein, and the conductive adhesive 212 after being solidified can fix the electrode 111, so as to fix the light emitting chip 110. In addition, the conductive adhesive 212 is provided with conductive particles, and after the conductive adhesive 212 is solidified, the conductive particles are communicated with each other, such that the conductive adhesive 212 can transmit an electrical signal to the electrode 111 of the light emitting chip 110. The conductive adhesive 212 is provided on a top of the conductive layer 211, so that the light emitting chip 110 can be well fixed through the cooperation of the conductive adhesive 212 and the conductive layer 211, and the conductive adhesive 212 can also provide the light emitting chip 110 with an electrical signal.

It is noted that when the growth substrate 100 and the transient substrate 220 are provided opposite to each other, which can be completed by aligning the markings on the growth substrate 100 with the markings on the transient substrate 220, or by aligning the electrode 111 of the light emitting chip 110 with the conductive adhesive 212, or by the combination of the two alignment methods.

In order to facilitate the transmission of electrical signals to the light emitting chip 110, a positive projection area of the conductive layer 211 on the transfer film layer 230 is larger than a positive projection area of the conductive adhesive 212 on the transfer film layer 230. As can be seen, a laid flat area of the conductive layer 211 in the horizontal direction is larger than a laid flat area of the conductive adhesive 212 in the horizontal direction. The conductive adhesive 212 cannot cover the entire conductive layer 211, and at least a portion of the conductive layer 211 is exposed. In this way, when the connection wire 500 is provided, an end of the connection wire 500 can be connected to the exposed portion of the conductive layer 211, thereby making full use of the good conductivity of the conductive layer 211.

In order to facilitate docking and fixing of the light emitting chip 110, the positive projection area of the conductive adhesive 212 on the transfer film layer 230 is larger than the positive projection area of the electrode 111 of the light emitting chip 110 on the transfer film layer 230. The conductive adhesive 212 has a larger laid flat area in the horizontal direction, but the electrode 111 of the light emitting chip 110 has a smaller laid flat area in the horizontal direction, so that when the light emitting chip 110 is docked to the transient substrate 220, the electrode 111 can be well docked to the conductive adhesive 212, so that the conductive adhesive 212 wraps well around the electrode 111 of the light emitting chip 110, such that the contact area of the conductive adhesive 212 and the electrode 111 is improved, and the light emitting chip 110 is well docked and fixed, and the transmission rate of the electrical signal can also be improved. The conductive adhesive 212 is coated on the conductive layer 211, it may be square or rhombus, to facilitate positioning of the electrode 111.

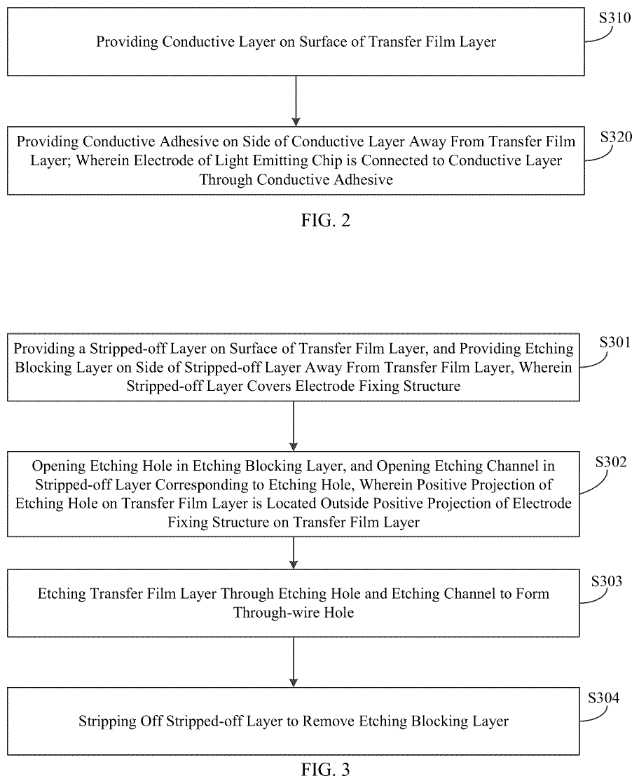

Referring to FIG. 3, the opening the through-wire hole 201 in the transfer film layer 230 adjacent to the electrode fixing structure 210 includes:

Step S301, providing a stripped-off layer 600 on a surface of the transfer film layer 230, and providing an etching blocking layer 700 on a side of the stripped-off layer 600 away from the transfer film layer 230, wherein the stripped-off layer 600 covers the electrode fixing structure 210, and the etching blocking layer 700 also covers the electrode fixing structure 210.

Step S302, opening an etching hole 710 in the etching blocking layer 700, and opening an etching channel 610 in the stripped-off layer 600 corresponding to the etching hole 710, wherein a positive projection of the etching hole 710 on the transfer film layer 230 is located outside a positive projection of the electrode fixing structure 210 on the transfer film layer 230. Since the positive projection of the etching hole 710 on the transfer film layer 230 is located outside the positive projection of the electrode fixing structure 210 on the transfer film layer 230, that is, the etching hole 710 avoids the electrode fixing structure 210, thus the electrode fixing structure 210 is not etched when the etching blocking layer 700 is etched.

Step S303, etching the transfer film layer 230 to form a through-wire hole 201 through the etching hole 710 and the etching channel 610. The etching hole 710 and the etching channel 610 are communicated to each other, that is, the positions at the etching hole 710 and the etching channel 610 are unaffected by the etching, and the etching process can directly etch the transfer film layer 230, to form the through-wire hole 201.

Step S304, stripping off the stripped-off layer 600 to remove the etching blocking layer 700. When a photoresist stripping solution is used to strip off the stripped-off layer 600, the etching blocking layer 700 is also stripped off at the same time as the etching blocking layer 700 is set on a top of the stripped-off layer 600, thus the operation of opening the through-wire hole 201 is completed. The stripped-off layer 600 may be understood as a photoresist layer. The etching blocking layer 700 may be a metal such as molybdenum, aluminium, copper, etc., or an inorganic material such as silicon nitride, silicon oxide, etc., and the etching blocking layer 700 has a thickness of 200 to 1000 nm. The etching blocking layer 700 is then dry-etched by gases such as oxygen or carbon tetrachloride, which have a very low rate of etching the etching blocking layer 700 and a very high rate of etching an organic membrane such as the transfer film layer 230, thereby forming a through-wire hole 201 in the transfer film layer 230, and then the etching blocking layer 700 and the stripped-off layer 600 are removed by the photoresist stripping solution or so on.

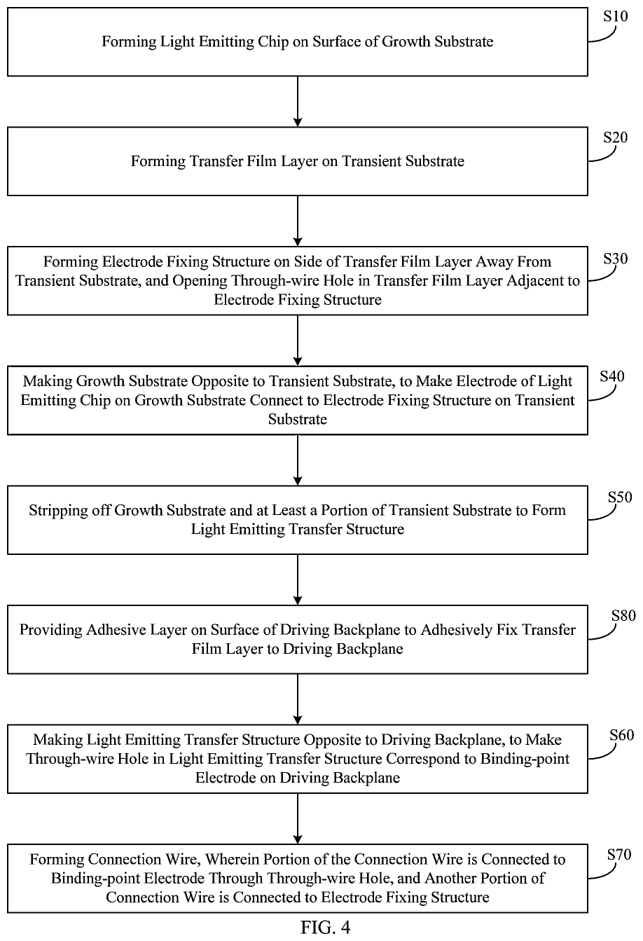

Referring to FIG. 4, before the transferring the light-emitting transfer structure 300 to the driver backplane 400 includes:

Step S80, providing an adhesive layer 420 on a surface of the driving backplane 400, to make the transfer film layer 230 to be adhesively fixed to the driving backplane 400. The adhesive layer 420 has a certain degree of adhesiveness, and the adhesive layer 420 can make good contact with the transfer film layer 230 to fix the transfer film layer 230 to the driving backplane 400, thereby completing the fixing of the light emitting transfer structure 300.

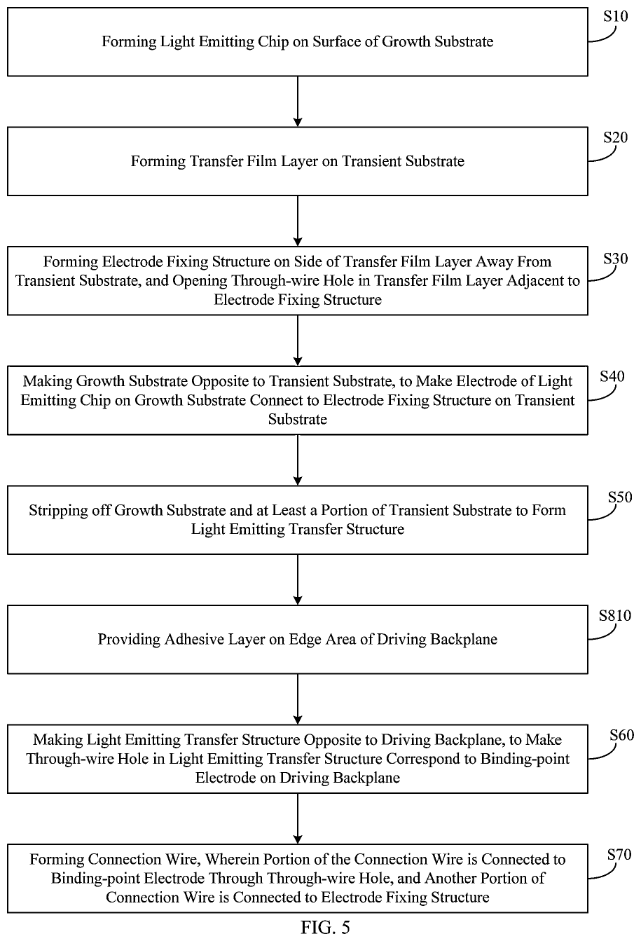

Referring to FIG. 5, there are a plurality of the light emitting chips 110, and the driving backplane 400 is provided with a mounting area for mounting the plurality of light emitting chips 110, and an edge area surrounding a periphery of the mounting area; and the providing the adhesive layer 420 on the surface of the driving backplane 400 includes:

Step S810, providing the adhesive layer 420 on the edge area of the driving backplane 400. The adhesive layer 420 is provided on the edge area of the driving backplane 400 to avoid affecting the setting of the binding-point electrode 410. In the display panel, the mounting area can be understood as a display area for the light emitting chip 110 to emit light to form a display screen. The edge area can be understood as a non-display area, the non-display area can be used for installing some wires and components and so on. For example, the adhesive layer 420 is provided in the non-display area to avoid affecting the display screen.

### Embodiment II

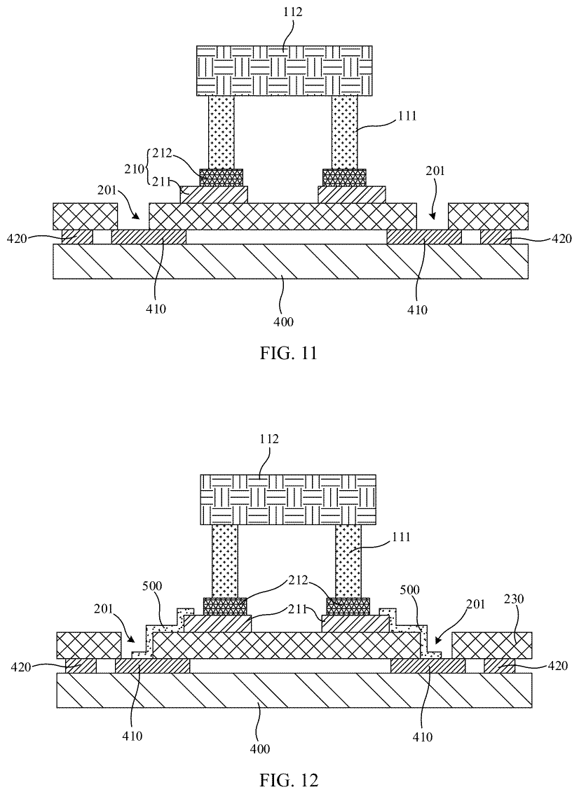

Referring to FIGS. 11 and 12, the present disclosure also provides a light emitting structure, which includes a driving backplane 400 and a light emitting transfer structure 300, the light emitting transfer structure 300 includes a transfer film layer 230, an electrode fixing structure 210 and a light emitting chip 110. The electrode fixing structure 210 is provided on the transfer film layer 230, the electrode 111 of the light emitting chip 110 is fixed to the electrode fixing structure 210. A binding-point electrode 410 is provided on a surface of the driving backplane 400, and the light emitting transfer structure 300 is provided on the driving backplane 400. The transfer film layer 230 is also provided with a through-wire hole 201, which is close to the electrode fixing structure 210 and corresponds to the binding-point electrode 410 of the driving backplane 400. The light emitting structure also includes a connection wire 500, which is provided inside the through-wire hole 201, and an end of the connection wire 500 is connected to the binding-point electrode 410 of the driving backplane 400, another end of the connection wire 500 is connected to the electrode fixing structure 210. The light emitting transfer structure 300 may also include a portion of the transient substrate 220, which is used to support the transfer film layer 230.

In this embodiment, when the light emitting transfer structure 300 is moved to the driving backplane 400, no stripping off operation of the laser is involved. The connection wire 500 is fabricated in the through-wire hole 201, and the connection wire 500 connects the binding-point electrode 410 on the driving backplane 400 to the electrode fixing structure 210. The connection wire 500 is fabricated after the light emitting transfer structure 300 is fixed to the driving backplane 400, and the connection wire 500 is also not affected by the stripping off operation of the laser, whereby the binding-point electrode 410 and the connection wire 500 can communicate normally, reducing abnormalities in the display screen.

Further, the electrode fixing structure 210 includes an anode fixing portion and a cathode fixing portion spaced from each other, the through-wire hole 201 includes an anode through-wire hole and a cathode through-wire hole, the anode through-wire hole is opened on a side of the anode fixing portion away from the cathode fixing portion, the cathode through-wire hole is opened on a side of the cathode through-wire hole away from the anode fixing portion, the anode through-wire hole and the cathode through-wire hole are provided respectively at both sides of the light emitting chip 110, to reduce obstruction to the connection wire 500 when the connection wire 500 is deposited, facilitating the setting of the connection wire 500.

In the present disclosure, generally speaking, the thickness of the transfer film layer 230 is about 10 microns, which is thicker and can support the light emitting chip 110. However, sometimes the texture of the fabricated transfer film layer 230 is softer and is easily bent, or due to the height limitation, the thickness of the transfer film layer 230 is thinner, which may cause the light emitting chip 110 to collapse, resulting in damage to the light emitting chip 110, or damage to the driving the backplane 400. For this reason, the present disclosure also provides two solutions.

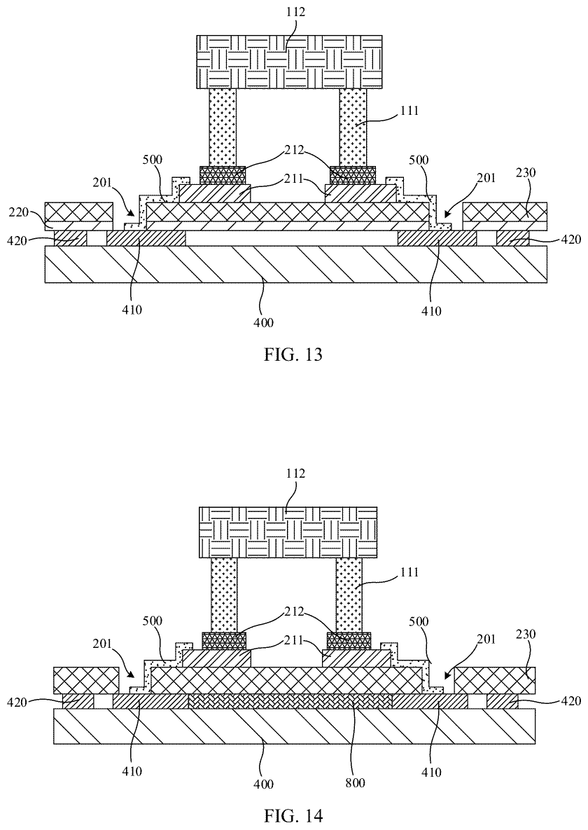

In the first solution, as shown in FIG. 13, the light emitting transfer structure 300 includes a transient substrate 220. The electrode fixing structure 210 is provided on the transfer film layer 230. The transfer film layer 230 is provided with a through-wire hole 201, the transient substrate 220 is provided between the transfer film layer 230 and the driving backplane 400, and the transient substrate 220 is provided with a through hole corresponding to the through-wire hole 201. Specifically, the transient substrate 220 may be retained before the light emitting transfer structure 300 is provided to the driving backplane 400, or the thickness of the transient substrate 220 may be reduced, and a portion of the transient substrate 220 is etched away to prevent the height from being too high. The transient substrate 220 has a certain hardness to support the light emitting chip 110 and prevents the light emitting chip 110 from collapsing. It should be noted that, at this time, the transient substrate 220 also needs to be opened with a through hole corresponding to the through-wire hole 201 of the transfer film layer 230, to ensure that the connection wire 500 can be connected to the driving backplane 400.

In a second solution, referring to FIG. 14, the light emitting structure includes a dielectric layer 800. The dielectric layer 800 is provided on the driving backplane 400, and a positive projection of the light emitting chip 110 on the driving backplane 400 is located within the positive projection of the dielectric layer 800 on the driving backplane 400. Specifically, before the light emitting transfer structure 300 is provided to the driving backplane 400, the dielectric layer 800 may be provided on the driving backplane 400 corresponding to the light emitting chip 110. The dielectric layer 800 is insulating, non-conductive, and has a certain degree of hardness. The dielectric layer 800 can support the light emitting chip 110 and avoid the collapse of the light emitting chip 110.

### Embodiment III

The present disclosure also provides a display panel, which includes a light emitting chip 110 and a driving backplane 400, and the method of transferring the light emitting chip 110 as described above is used in the display panel to transfer the light emitting chip 110 to the driving backplane 400.

The implementation and beneficial effects of the display panel are referred to the scheme of the method of transferring the light emitting chip, as described above, and will not be repeated herein.

Other embodiments of the present disclosure will readily come to mind to those skilled in the art upon consideration of the specification and practice of the invention disclosed herein. The present disclosure is intended to cover any variations, uses, or adaptations of the present disclosure that follow the general principles of the present disclosure and include means of common knowledge or customary skill in the art not disclosed herein.

It is to be understood that this application is not limited to the precise construction which has been described above and illustrated in the accompanying drawings, and that various modifications and changes may be made without departing from its scope. The scope of this application is limited only by the appended claims.

What is claimed is:

1. A method of transferring a light emitting chip, comprising:
forming a light emitting chip on a surface of a growth substrate;
forming a transfer film layer on a transient substrate;
forming an electrode fixing structure on a side of the transfer film layer away from the transient substrate, and opening a through-wire hole in the transfer film layer adjacent to the electrode fixing structure;
making the growth substrate opposite to the transient substrate, to make an electrode of the light emitting chip on the growth substrate connect to the electrode fixing structure on the transient substrate;
stripping off the growth substrate and at least a portion of the transient substrate to form a light emitting transfer structure;
making the light emitting transfer structure opposite to a driving backplane, to make a through-wire hole in the light emitting transfer structure correspond to a binding-point electrode on the driving backplane; and
forming a connection wire, wherein a portion of the connection wire is connected to the binding-point electrode through the through-wire hole, and another portion of the connection wire is connected to the electrode fixing structure.

2. The method of transferring the light emitting chip according to claim 1, wherein the forming the electrode fixing structure on the side of the transfer film layer away from the transient substrate comprises:
providing a conductive layer on a surface of the transfer film layer, and
providing a conductive adhesive on a side of the conductive layer away from the transfer film layer;
wherein the electrode of the light emitting chip is connected to the conductive layer through the conductive adhesive.

3. The method of transferring the light emitting chip according to claim 2, wherein a positive projection area of the conductive layer on the transfer film layer is larger than a positive projection area of the conductive adhesive on the transfer film layer, and
wherein the positive projection area of the conductive adhesive on the transfer film layer is larger than a positive projection area of the electrode of the light emitting chip on the transfer film layer.

4. The method of transferring the light emitting chip according to claim 1, wherein the opening the through-wire hole in the transfer film layer adjacent to the electrode fixing structure comprises:
providing a stripped-off layer on a surface of the transfer film layer, and providing an etching blocking layer on a side of the stripped-off layer away from the transfer film layer, wherein the stripped-off layer covers the electrode fixing structure;
opening an etching hole in the etching blocking layer, and opening an etching channel in the stripped-off layer corresponding to the etching hole, wherein a positive projection of the etching hole on the transfer film layer is located outside a positive projection of the electrode fixing structure on the transfer film layer;
etching the transfer film layer through the etching hole and the etching channel to form the through-wire hole; and
stripping off the stripped-off layer to remove the etching blocking layer.

5. The method of transferring the light emitting chip according to claim 1, wherein before the transferring the light emitting transfer structure to the driving backplane comprises:
providing an adhesive layer on a surface of the driving backplane to adhesively fix the transfer film layer to the driving backplane.

6. The method of transferring the light emitting chip according to claim 5, wherein the driving backplane is provided with a mounting area for mounting a plurality of light emitting chips, and an edge area surrounding a periphery of the mounting area;
wherein the providing the adhesive layer on the surface of the driving backplane comprises:
providing the adhesive layer on the edge area of the driving backplane.

7. The method of transferring the light emitting chip according to claim 1, wherein the light emitting chip comprises an epitaxial layer and electrodes, the forming the light emitting chip on the surface of the growth substrate comprises:
forming the epitaxial layer on the surface of the growth substrate, and
forming the electrodes on a top of the epitaxial layer.

8. The method of transferring the light emitting chip according to claim 1, wherein making the growth substrate opposite to the transient substrate means that the light emitting chip and the electrode fixing structure are opposite to each other, and the electrode of the light emitting chip is directly faced to the electrode fixing structure.

9. The method of transferring the light emitting chip according to claim 1, wherein electrodes of the light emitting chip comprises an anode and a cathode, and two through-wire holes are provided;
two binding-point electrodes on the driving backplane are provided, one of two binding-point electrodes is configured for providing an electrical signal to the anode of the light emitting chip and the other of the two binding-point electrodes is configured for providing electrical signals to the cathode of the light emitting chip.

10. The method of transferring the light emitting chip according to claim 9, wherein the electrode fixing structure comprises an anode fixing portion and a cathode fixing portion spaced from each other, the two through-wire holes comprise an anode through-wire hole and a cathode through-wire hole, the anode through-wire hole is opened on a side of the anode fixing portion away from the cathode fixing portion, the cathode through-wire hole is opened on a side of the cathode through-wire hole away from the anode fixing portion, the anode through-wire hole and the cathode through-wire hole are provided respectively at both sides of the light emitting chip.

11. The method of transferring the light emitting chip according to claim 2, wherein the conductive adhesive is provided with conductive particles, and after the conductive adhesive is solidified, the conductive particles are communicated with each other; and the conductive adhesive is provided on a top of the conductive layer.

12. A light emitting structure, comprising a light emitting transfer structure, wherein the light emitting transfer structure comprises a transfer film layer, an electrode fixing structure and a light emitting chip;
wherein the electrode fixing structure is provided on the transfer film layer, the transfer film layer is provided with a through-wire hole close to the electrode fixing structure, and an electrode of the light emitting chip is connected to the electrode fixing structure;
wherein the light emitting structure further comprises a driving backplane, a binding-point electrode is provided on a surface of the driving backplane, the light emitting transfer structure is provided on the driving backplane, and the through-wire hole corresponds to the binding-point electrode of the driving backplane; and
wherein the light emitting structure further comprises a connection wire, the connection wire is provided in the through-wire hole, an end of the connection wire is connected to the binding-point electrode and another end of the connection wire is connected to the electrode fixing structure.

13. The light emitting structure according to claim 12, wherein the light emitting transfer structure comprises a transient substrate provided between the transfer film layer and the driving backplane, and the transient substrate is provided with a through-hole corresponding to the through-wire hole.

14. The light emitting structure according to claim 12, wherein the light emitting structure comprises a dielectric layer provided on the driving backplane, and a positive projection of the light emitting chip on the driving backplane is located within a positive projection of the dielectric layer on the driving backplane.

15. The light emitting structure according to claim 12, wherein the electrode fixing structure comprises an anode fixing portion and a cathode fixing portion spaced from each other, two through-wire holes comprising an anode through-wire hole and a cathode through-wire hole, the anode through-wire hole is opened on a side of the anode fixing portion away from the cathode fixing portion, the cathode through-wire hole is opened on a side of the cathode through-wire hole away from the anode fixing portion, the anode through-wire hole and the cathode through-wire hole are provided respectively at both sides of the light emitting chip.

16. A display panel, comprising a light emitting chip and a driving backplane, wherein a method of transferring the light emitting chip is used by the display panel to transfer the light emitting chip to the driving backplane;
wherein the method comprises:
forming a light emitting chip on a surface of a growth substrate;
forming a transfer film layer on a transient substrate;
forming an electrode fixing structure on a side of the transfer film layer away from the transient substrate, and opening a through-wire hole in the transfer film layer adjacent to the electrode fixing structure;
making the growth substrate opposite to the transient substrate, to make an electrode of the light emitting chip on the growth substrate connect to the electrode fixing structure on the transient substrate;
stripping off the growth substrate and at least a portion of the transient substrate to form a light emitting transfer structure;
making the light emitting transfer structure opposite to a driving backplane, to make a through-wire hole in the light emitting transfer structure correspond to a binding-point electrode on the driving backplane; and
forming a connection wire, wherein a portion of the connection wire is connected to the binding-point electrode through the through-wire hole, and another portion of the connection wire is connected to the electrode fixing structure.

17. The display panel according to claim 16, wherein the forming the electrode fixing structure on the side of the transfer film layer away from the transient substrate comprises:
providing a conductive layer on a surface of the transfer film layer, and
providing a conductive adhesive on a side of the conductive layer away from the transfer film layer;
wherein the electrode of the light emitting chip is connected to the conductive layer through the conductive adhesive.

18. The display panel according to claim 17, wherein a positive projection area of the conductive layer on the transfer film layer is larger than a positive projection area of the conductive adhesive on the transfer film layer, and
wherein the positive projection area of the conductive adhesive on the transfer film layer is larger than a positive projection area of the electrode of the light emitting chip on the transfer film layer.

19. The display panel according to claim 16, wherein the opening the through-wire hole in the transfer film layer adjacent to the electrode fixing structure comprises:
providing a stripped-off layer on a surface of the transfer film layer, and providing an etching blocking layer on a side of the stripped-off layer away from the transfer film layer, wherein the stripped-off layer covers the electrode fixing structure;
opening an etching hole in the etching blocking layer, and opening an etching channel in the stripped-off layer corresponding to the etching hole, wherein a positive projection of the etching hole on the transfer film layer is located outside a positive projection of the electrode fixing structure on the transfer film layer;
etching the transfer film layer through the etching hole and the etching channel to form the through-wire hole; and
stripping off the stripped-off layer to remove the etching blocking layer.

20. The display panel according to claim 16, wherein before the transferring the light emitting transfer structure to the driving backplane comprises:
providing an adhesive layer on a surface of the driving backplane to adhesively fix the transfer film layer to the driving backplane.
